(19) United States
(12) Patent Application Publication
(10) Pub. No.: US 2015/0124182 A1
(43) Pub. Date: May 7, 2015

(54) TOUCH PANEL AND DISPLAY DEVICE WITH THE TOUCH PANEL

(71) Applicant: Hannstouch Solution Incorporated, Tainan (TW)

(72) Inventors: Ming-Liang Chen, Tainan (TW); Chih-Wei Chen, Tainan (TW); Ching-Feng Tsai, Tainan (TW)

(21) Appl. No.: 14/529,146

(22) Filed: Oct. 31, 2014

(30) Foreign Application Priority Data
Nov. 1, 2013 (TW) 102220464

(51) Int. Cl. H05K 1/02; G06F 3/041

(52) U.S. Cl. CPC H05K 1/0296; G06F 3/041; H05K 2201/10128
USPC 349/12; 174/268; 29/846

(57) ABSTRACT

A display device with a touch panel is disclosed. The display device with the touch panel includes: a sensor having a substrate, a sensing electrode layer and a protective layer with a plurality of protrusions, wherein the sensing electrode layer is configured between the substrate and the protective layer; and a display module disposed under the sensor, wherein the sensor is connected to the display module with a glue, and the glue is configured along a periphery of the sensor.

### CROSS-REFERENCE TO RELATED APPLICATION AND CLAIM OF PRIORITY

This application claims the benefit of Taiwan Patent Application No. 102220464, filed on Nov. 1, 2013, at the Taiwan Intellectual Property Office, the disclosures of which are incorporated herein in their entirety by reference.

### FIELD OF THE INVENTION

The present invention relates to a display device with a touch panel.

### BACKGROUND OF THE INVENTION

In the present bonding techniques for a touch panel and a liquid crystal display module (LCM), air bonding or bonding in hydrogels is the is usual way to bond the touch panel and LCM together. Please refer to FIG. 1, which shows a schematic diagram illustrating a structure of a touch panel and a display module after air bonding. The structure 100 includes a display module 101, a touch panel 102, a glue 103 and an air gap 104, where the air gap 104 results from the bonding step using the glue. Please refer to FIG. 2, which shows a schematic diagram illustrating a structure of a touch panel and a display module after bonding with hydrogels (non-air bonding/optical bonding). The structure 200 includes a display module 201, a touch panel 202 and a hydrogel 204.

However, the skilled person in the art knows that bonding the touch panel and the display module together using the air bonding technique will cause the phenomenon of Newton ring and decrease the optical property. Although using hydrogels to bond the touch panel and the display module together can overcome the defect resulting from the air bonding technique for small sized touch panels and display modules, it will cause the problems of generating bubbles and lower yield, which increases the cost of manufacturing the large sized touch panels and display modules.

Therefore, it would be useful to invent a display device with a touch panel that circumvents all the above issues. In order to fulfill this need the inventors have proposed an invention “TOUCH PANEL AND DISPLAY DEVICE WITH THE TOUCH PANEL.” The summary of the present invention is described as follows.

### SUMMARY OF THE INVENTION

In accordance with an aspect of the present invention, a touch panel includes a substrate, a sensing electrode layer and a protective layer. The sensing electrode layer is disposed on the substrate, and the protective layer is disposed on the sensing electrode layer and has a plurality of protrusions.

In accordance with another aspect of the preset invention, a display device with a touch panel is disclosed. The display device with the touch panel includes a sensor and a display module. The sensor has a substrate, a sensing electrode layer and a protective layer with a plurality of protrusions, where the sensing electrode layer is configured between the substrate and the protective layer. The display module is disposed under the sensor, where the sensor is connected to the display module with glue, and the glue is configured along a periphery of the sensor.

The above objectives and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 shows a schematic diagram illustrating a structure of a touch panel and a display module after air bonding;

FIG. 2 shows a schematic diagram illustrating a structure of a touch panel and a display module after bonding with hydrogels;

FIGS. 3A and 3B show a schematic diagram illustrating the structure of the first embodiment of the present invention;

FIGS. 4A and 4B show a schematic diagram illustrating the structure of the second embodiment of the present invention;

FIGS. 5 and 6 show top views of the configuration of the protrusions of the present invention;

FIG. 7 shows a schematic diagram illustrating the structure of the third embodiment of the present invention;

FIG. 8 shows a schematic diagram illustrating the structure of the fourth embodiment of the present invention; and

FIG. 9 is a flow chart schematically showing the manufacturing method for a display device with a touch panel of the present invention.

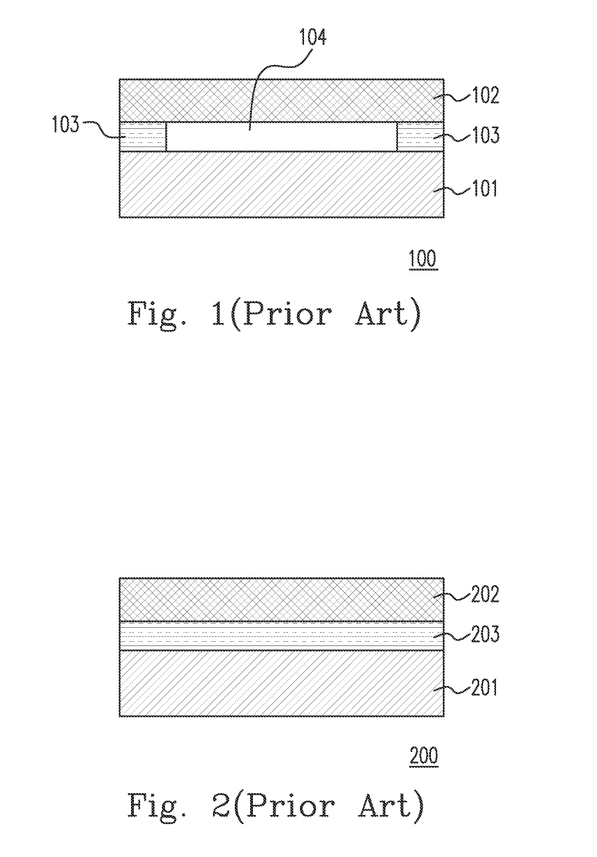

### DETAILED DESCRIPTION OF THE PREFERRED EMBODIMENTS

The present invention will now be described more specifically with reference to the following embodiments. It is to be noted that the following descriptions of preferred embodiments of this invention are presented herein for the purposes of illustration and description only; they are not intended to be exhaustive or to be limited to the precise form disclosed.

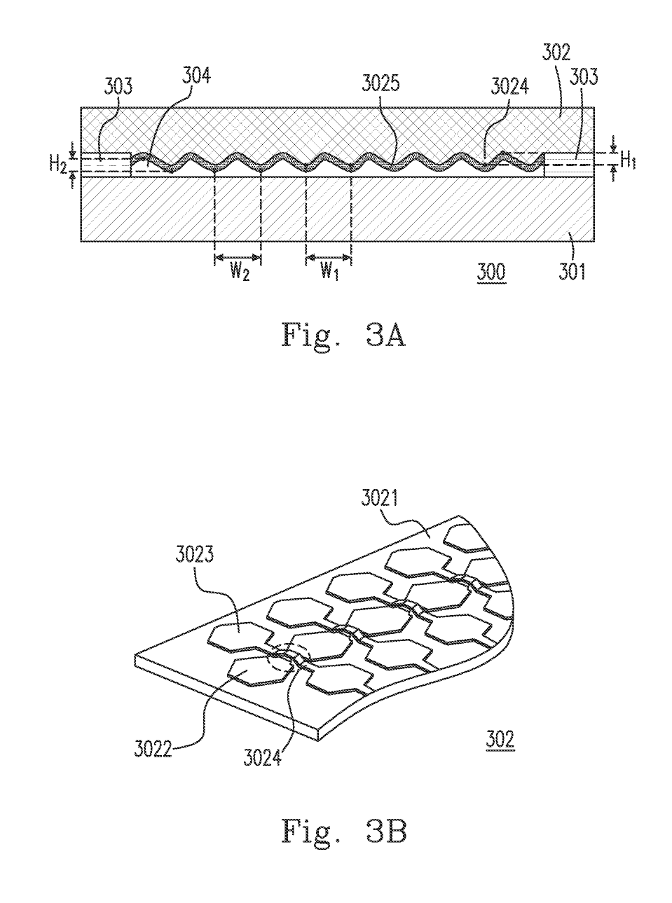

Please refer to FIGS. 3A and 3B, which show a schematic diagram illustrating the structure of the first embodiment of the present invention, where the structure 300 includes a display module 301, a sensor 302, a glue 303 and an air gap 304, wherein the glue 303 includes paste, OCA (Optical Clear Adhesive), UV glue and double-sided tape, etc. The specific structure of the sensor 302 is shown as FIG. 3B, and the sensor 302 at least includes a substrate 3021. There are a plurality of sensing electrodes, and the plurality of sensing electrodes include a plurality of X-axis sensing electrodes 3022 and a plurality of Y-axis sensing electrodes 3023, where a bridge portion 3024 with a protrusion shape is at the intersection of each X-axis sensing electrode 3022 and each Y-axis sensing electrode 3023 and a protective layer (cover layer) 3025 is configured on the plurality of X-axis sensing electrodes 3022 and the plurality of Y-axis sensing electrodes 3023. Namely, the protective layer (cover layer) 3025 is disposed on the side of the substrate that has the bridge portion 3024, i.e. the bonding surface bonding to the display module 301. The protective layer (cover layer) 3025 forms a plurality of protrusions with the structure in a protrusion shape of the bridge portion 3024 (as shown in FIG. 3A). In addition, the display module 301 and the sensor 302 are attached to each other with the glue 303 and then the air gap 304 is formed. The glue 303 of the embodiment can be double-side tape, but is not limited thereto. In this embodiment, the glue is configured around the edges of the sensor 302. Because the plurality of protrusions formed by the protective layer (cover layer) 3025 and the bridge portion 3024 can increase the recovery speed after the sensor 302 is pressed and then contacts the surface of the display module 301, the phenomenon of Newton ring caused by the use of the sensor 302 can be decreased.

Preferably, the protective layer (cover layer) 3025 is formed in the last step in the process of manufacturing the sensor 302, the protective layer (cover layer) 3025 is formed by coating thin photoresist or optical resin on the substrate 3021, or formed of hardcoat material, and Silicon dioxide (SiO₂) is the material often used in the process. In addition, in another embodiment, optically clear adhesive (OCA) can be filled into the air gap 304. In this embodiment, the height of the air gap 304 or the thickness of the glue 303 can be 40 to 150 μm (preferably 50 μm), the height H₁ of the protrusion of the bridge portion 3024 can be 1.5 to 5 μm (preferably 2 μm), the distance W₁ between each neighboring bridge portion 3024 can be 3 to 5 μm, and the entire thickness of the protective layer (cover layer) 3025 is almost uniform, where the thickness can be 0.5 to 1.5 μm (preferably 1 μm). In the embodiment, the protective layer 3025 with a thinner thickness is formed on the surface with the X-axis electrodes 3022 and the Y-axis electrodes 3023 of the sensor 302, the structure of the protrusions at the intersections of the X-axis electrodes 2022 and the Y-axis electrodes 3023 causes the surface facing the display module 301 of the protective layer 3025 to correspondingly form a plurality of protrusions, namely the protrusions respectively correspond to the bridge portions. Therefore, the height H₂ of the protrusion of the protective layer substantially equals the height H₁ of the bridge portion, i.e. about 1.5 to 5 μm. Also, the distance W₂ between each neighboring protrusion of the protective layer 3025 substantially equals to the width W₁, i.e. about 3 to 5 μm.

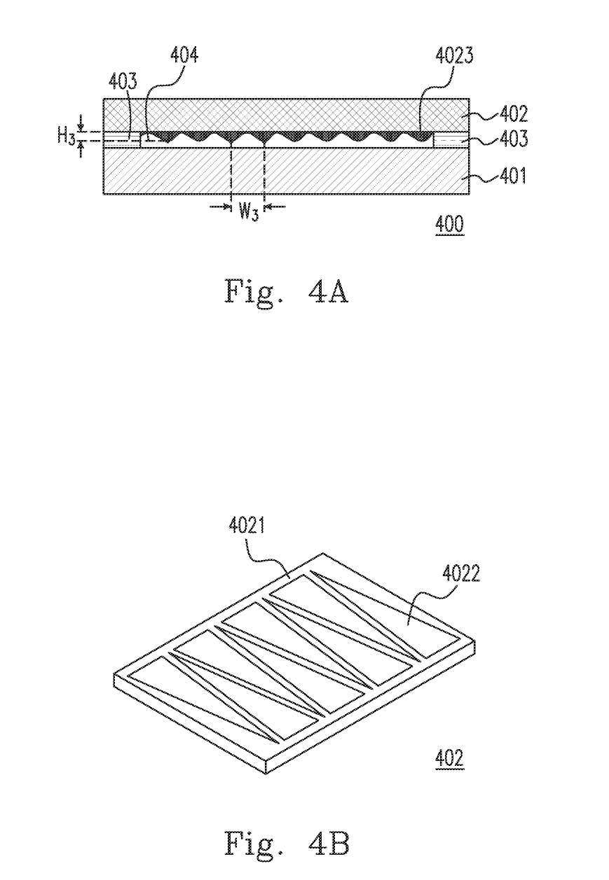

Please refer to FIGS. 4A and 4B, which show a schematic diagram illustrating the structure of the second embodiment of the present invention, where the structure 400 includes a display module 401, a sensor 402, a glue 403 and an air gap 404. The specific structure of the sensor 402 is shown as FIG. 4B, and the sensor 402 at least includes a substrate 4021, a plurality of sensing electrode strips 4022 and a protective layer (cover layer) 4023, where the protective layer (cover layer) 4023 is disposed on the surfaces of the substrate 4021 and the plurality of sensing electrode strips 4022 and includes a plurality of protrusions, and the display module 401 and the sensor 402 are attached to each other with the glue 403 and thus the air gap 404 is formed. Because the plurality of protrusions of the protective layer (cover layer) 4023 can increase the recovery function after the sensor 402 is pressed, the phenomenon of Newton ring caused by the use of the sensor 402 can be decreased. It is noted that the structure of the sensing electrode of this embodiment is different than that of the X-Y axis structure as shown in FIG. 3B, and it is a one-layer electrode or a single layer electrode. However, in another embodiment, the plurality of sensing electrode strips 4022 can be replaced with the X-Y axis sensing electrodes as shown in FIG. 3B.

Preferably, the protective layer (cover layer) 4023 with the plurality of protrusions is formed in the last step, the overcoat 2 (OC2) step, in the process of manufacturing the sensor 402, and the OC2 step uses the half-tone procedure in the photolithography process to form the plurality of protrusions. In addition, in another embodiment, optically clear adhesive can be filled into the air gap 404. In this embodiment, the height of the air gap 404 or the thickness of the glue 403 can be 40 to 150 μm (preferably 50 μm), the height H₃ of the protrusion can be 2 to 6 μm, the distance W₃ between each protrusion can be 3 to 5 μm. The protective layer (cover layer) 4023 is generally formed of photoresist material. In the embodiment, a thicker protective layer 4023 will be formed by coating a thick photoresist (or optical resin) on the surface of the sensor 402, and then performing a photolithography process, such as a half-tone procedure, on the thick photoresist to form a plurality of protrusions on the protective layer 4023.

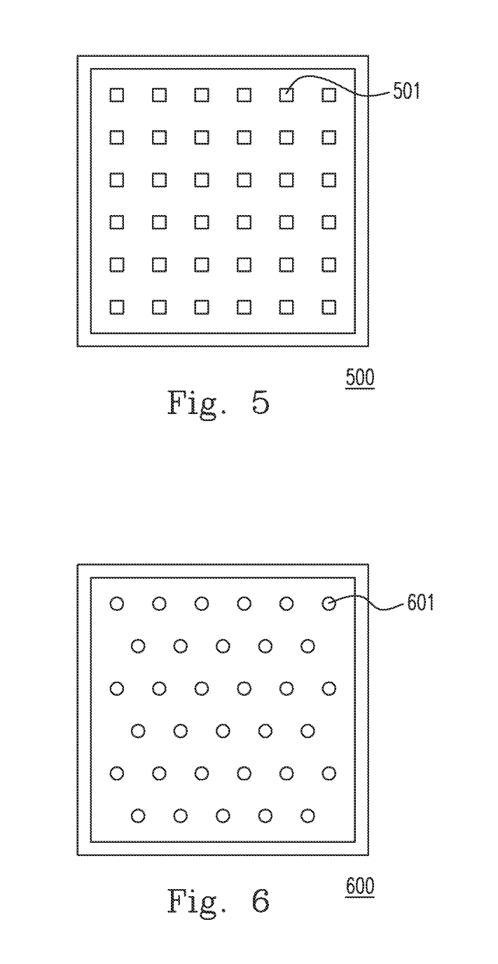

Please refer to FIGS. 5 and 6, which show top views of the configuration of the protrusions of the present invention, where the configuration of protrusions 500 includes a plurality of protrusions 501, and the configuration of protrusions 600 includes a plurality of protrusions 601. The protrusions 501 in the configuration of protrusions 500 are arranged in the way that any protrusion 501 has the same distance from the front one, the left one, the right one and the rear one, and the cross section of the protrusion 501 is a square. The protrusions 601 in the configuration of protrusions 601 are arranged in an interlacing way, and the cross section of the protrusion 601 is a circle. Furthermore, the configuration of protrusions can be arranged in other ways, such as in a concentric circle. No matter which way is used to arrange the protrusions, the preferable design is that the distance between each protrusion is 3 to 5 μm and the radius or width/length of the cross section of the protrusion is 10 to 30 μm.

In addition, the shape of the cross section of the protrusion can be designed on demand, such as a rectangle, a polygon, a circle and so on. Taking the structure 300 in FIG. 3A as an example, because the protrusions are formed by coating the cover layer on the bridge portion, the shape of the cross section of the protrusions can be determined by designing the bridge portion at the intersection of the X-axis pattern and Y-axis pattern. Taking the structure 400 in FIG. 4A as an example, because the protrusions are formed only by the cover layer, the shape of the cross section of the protrusions can be determined by designing a photolithography process, preferably by designing a gray-tone mask or a half-tone mask.

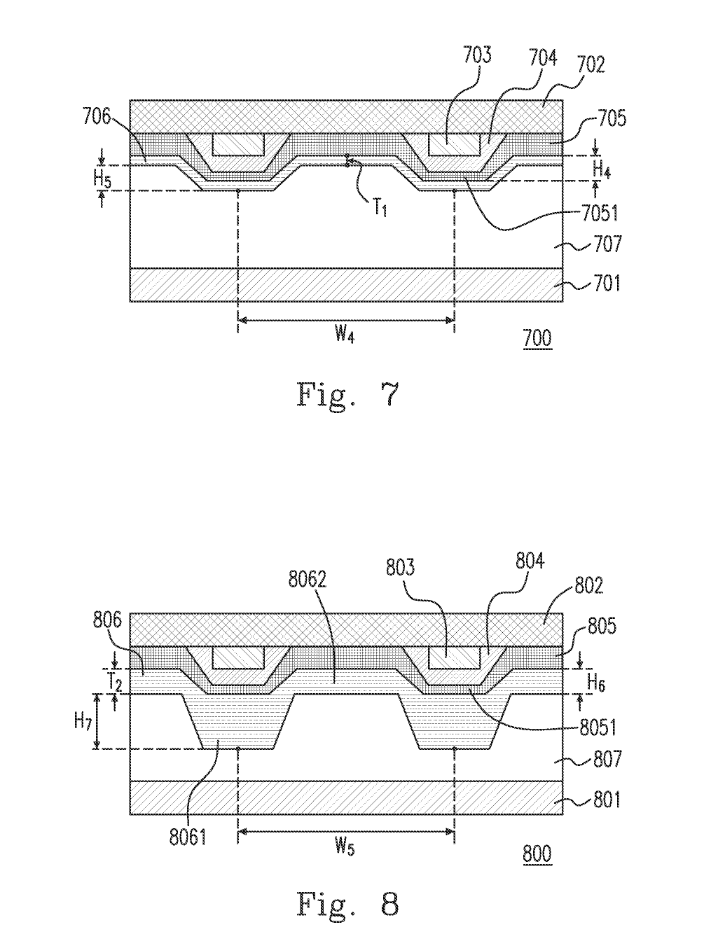

Please refer to FIG. 7, which shows a schematic diagram illustrating the structure of the third embodiment of the present invention, where the structure 700 includes a display module 701, a substrate 702, a first electrode layer 703, an isolation layer 704, a second electrode layer 705 having a bridge portion 7051, a protective layer (cover layer) 706 and an air gap 707. The first electrode layer 703 is disposed under the substrate 702 and covers a portion of the substrate 702, the isolation layer 704 covers the first electrode layer 703 so as to isolate the first electrode layer 703 from the second electrode layer 705, the second electrode layer 705 is disposed under the substrate 702 and covers a portion of the substrate 702, the bridge portion 7051 is configured under the isolation layer 704 so as to electrically isolate the first electrode layer 703 from the second electrode layer 705, the protective layer (cover layer) 706 covers the substrate 702, the first electrode layer 703 and the second electrode layer 705, the protective layer (cover layer) 706 forms a protrusion by the protruding structure of the bridge portion 7051, and the elements above form a sensor. When the sensor above is connected to the display module 701, the air gap 707 will be formed between the display module 701 and the protective layer (cover layer) 706.

Preferably, the sensor above is a touch panel, the first electrode layer 703 is an X-axis electrode layer having sensing patterns, the second electrode layer 705 is a Y-axis electrode layer having sensing patterns, the display module 701 and the touch panel are connected with glue, the protective layer (cover layer) 706 is formed by a coating of thin photoresist or optical resin, or formed by hardcoat material, and Silicon dioxide (SiO₂) is the material often used in the process. In addition, optically clear adhesive (OCA) can be filled into the air gap 707, the substrate 702 can be a transparent film, a transparent glass, a transparent plastic plate and so on, the height of the air gap 707 can be 40 to 150 μm (preferably 50 μm), the height H₄ of the bridge portion 7051 can be 1.5 to 5 μm (preferably 2 μm), the distance W₄ between each neighboring bridge portion 7051 can be 3 to 5 μm, and the entire thickness of the protective layer (cover layer) 706 is almost uniform, where the thickness T₁ can be 0.5 to 1.5 μm (preferably 1 μm). In addition, the height H₅ of the protrusion of the protective layer 706 substantially equals the height H₄ of the bridge portion 7051, i.e. about 1.5 to 5 μm.

Please refer to FIG. 8, which shows a schematic diagram illustrating the structure of the fourth embodiment of the present invention, where the structure 800 includes a display module 801, a substrate 802, a first electrode layer 803, an isolation layer 804, a second electrode layer 805 having a bridge portion 8051, a protective layer (cover layer) 806 having protrusion portions 8061 and recession portions 8062, and an air gap 807, where each of the recession portions 8062 is disposed between the two adjacent protrusion portions 8061. The first electrode layer 803 is disposed under the substrate 802 and covers a portion of the substrate 802, the isolation layer 804 covers the first electrode layer 803 so as to isolate the first electrode layer 803 from the second electrode layer 805, the second electrode layer 805 is disposed under the substrate 802 and covers a portion of the substrate 802, the bridge portion 8051 crosses the isolation layer 804, the protective layer (cover layer) 806 covers the substrate 802, the first electrode layer 803 and the second electrode layer 805, the protective layer (cover layer) 806 has the protrusion portions 8061 and the recession portions 8062, and the elements above form a sensor. When the sensor above connects to the display module 801, the air gap 807 will be formed between the display module 801 and the protective layer (cover layer) 806. The height H₇ of the protrusion portions 8061 can be 2 to 6 μm, the distance W₅ between each neighboring protrusion portions 8061 can be 3 to 5 μm, and the thickness T₂ of the recession portions 8062 is substantially equal to or higher than the height H₆ of the bridge portion 8051, or ranges between 1.5 and 5 μm.

The difference between the structure 700 in FIG. 7 and the structure 800 in FIG. 8 lies in the formation method of the protrusions, which is determined by the last step in the manufacturing process of the sensor. The protrusions of the protective layer (cover layer) 706 of the structure 700 are mainly formed by the protrusion structure of the bridge portion 7051. Because the protective layer (cover layer) 706 is a structure with a thin film thickness and is formed by a coating of thin photoresist or optical resin, the height of the protrusion of the structure 700 is mainly determined by the height of the bridge portion. The protrusions of the structure 800 mainly result from using a photolithography process for the protective layer (cover layer) 806 to directly form the protrusion portions 8061, and so the height of the protrusions of the structure 800 is determined during certain steps in the manufacturing process, such as designing a gray-tone mask, a half-tone mask and so on. In addition, the entire thickness of the protective layer (cover layer) 706 of the structure 700 is almost uniform, and the protective layer (cover layer) 806 of the structure 800 has the thin recession portions 8062 and the thick protrusion portions 8061, namely, the thickness of the protective layer 806 is not uniform.

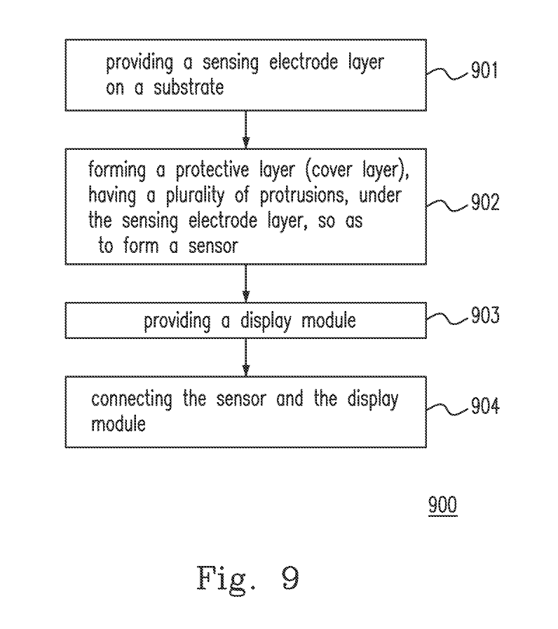

Please refer to FIG. 9, which is a flow chart schematically showing the manufacturing method for a display device with a touch panel of the present invention. The steps of the manufacturing method 900 are illustrated as follows.

Step 901: Providing a sensing electrode layer on a substrate. Preferably, the sensing electrode layer has an X-axis electrode layer and a Y-axis electrode layer, or a single layer sensing electrode.

Step 902: Forming a protective layer (cover layer), having a plurality of protrusions, under the sensing electrode layer, so as to form a sensor. Preferably, the sensor is a touch panel, and forming the protective layer (cover layer) is the last step in the manufacturing process for the sensor. In other words, once the protective layer (cover layer) is formed, the touch panel is almost complete. If the sensing electrode layer of the sensor has bridge portions, such as the intersections of the X-axis electrode layer and the Y-axis electrode layer via an isolation layer, the step of forming the protective layer (cover layer) can be an overcoating process, i.e. forming a thin protective layer on the X-axis electrode layer and the Y-axis electrode layer, and so the bridge portions with the protruding structure can form the plurality of protrusions in the final step of the manufacturing process for the sensor. In addition, in another embodiment, a photolithography process can be used to form the protective layer (cover layer), and directly form a plurality of protrusions in the protective layer (cover layer). If the sensing electrode layer in the sensor does not have bridge portions, such as the structure of the single layer sensing electrode as shown in FIG. 4B, the step of forming the protective layer (cover layer) can be a photolithography process, such as a half-tone process and so on, so as to directly form the plurality of protrusions in the protective layer (cover layer) in the last step of the manufacturing process for the sensor.

Step 903: Providing a display module. Preferably, the display module is an LCD display module (LCM).

Step 904: Connecting the sensor and the display module. Preferably, the sensor and the display module are connected by using the glue configured around the four edges (or periphery) of the sensor.

The display device with the touch panel is disclosed in the present invention, and the plurality of protrusions can be directly formed in the manufacturing process of the sensor. The recovery speed can be increased using the plurality of protrusions after the sensor is pressed, and so the phenomenon of Newton ring caused by the use of the sensor can be decreased. Using the display device with the touch panel disclosed in the present invention does not affect the optical properties of the display device. In addition, because the plurality of protrusions of the display device with the touch panel disclosed in the present invention are formed once the protective layer (cover layer) is formed, the manufacturing cost can be decreased.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A touch panel, comprising:
a substrate;
a sensing electrode layer disposed on the substrate; and
a protective layer disposed on the sensing electrode layer and having a plurality of protrusions.

2. The touch panel as claimed in claim 1, wherein the plurality of protrusions of the protective layer is formed using a photolithography process.

3. The touch panel as claimed in claim 2, wherein the photolithography process is a half-tone process.

4. The touch panel as claimed in claim 1, wherein the sensing electrode layer has a plurality of X-axis electrodes and a plurality of Y-axis electrodes, the plurality of X-axis electrodes and the plurality of Y-axis electrodes form a plurality of protruding bridge portions at respective intersections of the plurality of X-axis electrodes and the plurality of Y-axis electrodes, and the protective layer further includes a plurality of recession portions, each of which is disposed between two adjacent ones of the plurality of protrusions.

5. The touch panel as claimed in claim 4, wherein the plurality of protrusions correspond to the plurality of protruding bridge portions respectively.

6. The touch panel as claimed in claim 4, wherein the plurality of protrusions have a height equal to that of the plurality of protruding bridge portions.

7. The touch panel as claimed in claim 6, wherein each of the plurality of protrusions has a height ranging between 2 to 6 μm.

8. The touch panel as claimed in claim 1, wherein the sensing electrode layer has a plurality of X-axis electrodes and a plurality of Y-axis electrodes, the plurality of X-axis electrodes and the plurality of Y-axis electrodes form a plurality of protruding bridge portions at respective intersections of the plurality of X-axis electrodes and the plurality of Y-axis electrodes, and the plurality of protrusions correspond to the plurality of protruding bridge portions respectively.

9. The touch panel as claimed in claim 8, wherein the protective layer has a uniform thickness ranging between 0.5 to 0.15 μm.

10. The touch panel as claimed in claim 8, wherein the plurality of protruding bridge portions have a height ranging between 1.5 to 5 μm, and the plurality of protrusions of the protective layer have a height substantially equal to that of the plurality of protruding bridge portions.

11. The touch panel as claimed in claim 1, wherein the sensing electrode layer has a one-layer structure, and the protective layer further includes a plurality of recession portions, each of which is disposed between two adjacent ones of the plurality of protrusions.

12. The touch panel as claimed in claim 1, wherein two adjacent ones of the plurality of protrusions have a distance ranging between 2 to 6 μm.

13. A display device, comprising:
a sensor including a substrate, a sensing electrode layer and a protective layer having a plurality of protrusions, wherein the sensing electrode layer is configured between the substrate and the protective layer; and
a display module configured under the sensor, wherein the sensor and the display module are connected with a glue and the glue is configured around a periphery of the sensor.

14. The display device as claimed in claim 13, wherein there is an air gap among the protective layer, the display module and the glue.

15. The display device as claimed in claim 13 further comprising an optically clear adhesive (OCA) configured in a space formed among the protective layer, the display module and the glue.

16. The display device as claimed in claim 13, wherein the sensing electrode layer has a plurality of X-axis electrodes and a plurality of Y-axis electrodes, the plurality of X-axis electrodes and the plurality of Y-axis electrodes form a plurality of protruding bridge portions at respective intersections of the plurality of X-axis electrodes and the plurality of Y-axis electrodes, and the plurality of protrusions of the protective layer correspond to the plurality of protruding bridge regions respectively.

17. The display device as claimed in claim 13, wherein the sensing electrode layer has a one-layer structure, and the protective layer further includes a plurality of recession portions, each of which is disposed between two adjacent ones of the plurality of protrusions.

18. The display device as claimed in claim 13, wherein a distance between the substrate and the display module ranges between 50 to 150 μm.

19. A method for manufacturing a touch panel, comprising:
providing a substrate;
forming a sensing electrode layer disposed on the substrate; and
forming a protective layer having a plurality of protrusions, and disposed on the sensing electrode layer so as to form a sensor.

20. The method as claimed in claim 19 further comprising:
providing a display module; and
connecting the sensor to the display module.

21. The method as claimed in claim 19, wherein the sensing electrode layer has a plurality of X-axis electrodes and a plurality of Y-axis electrodes, the sensing electrode layer forming step further comprises forming a plurality of protruding bridge portions at respective intersections of the plurality of X-axis electrodes and the plurality of Y-axis electrodes, and the plurality of protrusions of the protective layer are formed by the plurality of bridge portions respectively.
